(19) United States
(12) Patent Application Publication
(10) Pub. No.: US 2026/0136662 A1
(43) Pub. Date: May 14, 2026

(54) SEMICONDUCTOR DEVICE AND FABRICATING METHOD THEREOF

(71) Applicant: TAIWAN SEMICONDUCTOR MANUFACTURING COMPANY, LTD., Hsinchu (TW)

(72) Inventors: Jer-Fu WANG, Taipei City (TW); Hung-Li CHIANG, Taipei City (TW)

(73) Assignee: TAIWAN SEMICONDUCTOR MANUFACTURING COMPANY, LTD., Hsinchu (TW)

(21) Appl. No.: 18/946,723

(22) Filed: Nov. 13, 2024

(51) Int. Cl. H01L 27/118

(52) U.S. Cl. CPC H10D 84/907; H10D 84/948; H10D 84/966

(57) ABSTRACT

A device includes a first gate structure, a second gate structure, a third gate structure and a first conductive segment. The first gate structure corresponds to a control terminal of a first switch. The second gate structure corresponds to a control terminal of a second switch. The third gate structure corresponds to a control terminal of a third switch, and coupled to the first gate structure. The first conductive segment is configured to couple the first switch, the second switch and the third switch to each other, and disposed between the second gate structure and the third gate structure. A distance between the first gate structure and the second gate structure is approximately equal to a distance between the third gate structure and the second gate structure.

### BACKGROUND

Some semiconductor devices include transmission gates. Some transmission gates need split gate structure. In complementary field-effect transistor (CFET) technologies, the processes of gate isolation (GI) and vertical local interconnect (VLI) are challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device, illustrated in accordance with some embodiments of the present disclosure.

FIG. 2A is a layout diagram a part of a semiconductor device shown in FIG. 1, illustrated in accordance with some embodiments of the present disclosure.

FIG. 2B is a layout diagram of another part of the semiconductor device shown in FIG. 1, illustrated in accordance with some embodiments of the present disclosure.

FIG. 3 is a circuit diagram of a semiconductor device corresponding to the semiconductor device shown in FIG. 1, illustrated in accordance with some embodiments of the present disclosure.

FIG. 4 is a circuit diagram of a semiconductor device corresponding to the semiconductor device shown in FIG. 1, illustrated in accordance with some embodiments of the present disclosure.

FIG. 5A is a circuit diagram of a semiconductor device corresponding to the semiconductor device shown in FIG. 1, illustrated in accordance with some embodiments of the present disclosure.

FIG. 5B is a circuit diagram of a semiconductor device corresponding to the semiconductor device shown in FIG. 5A, illustrated in accordance with some embodiments of the present disclosure.

FIG. 6 is a flowchart diagram of a method for fabricating the memory devices described above, illustrated in accordance with some embodiments of the present disclosure.

FIG. 7 is a schematic view of a system for designing and manufacturing at least one of the semiconductor devices described above, illustrated in accordance with some embodiments of the present disclosure.

FIG. 8 is a block diagram of an integrated circuit (IC)/semiconductor device manufacturing system, and an IC manufacturing flow associated therewith, illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

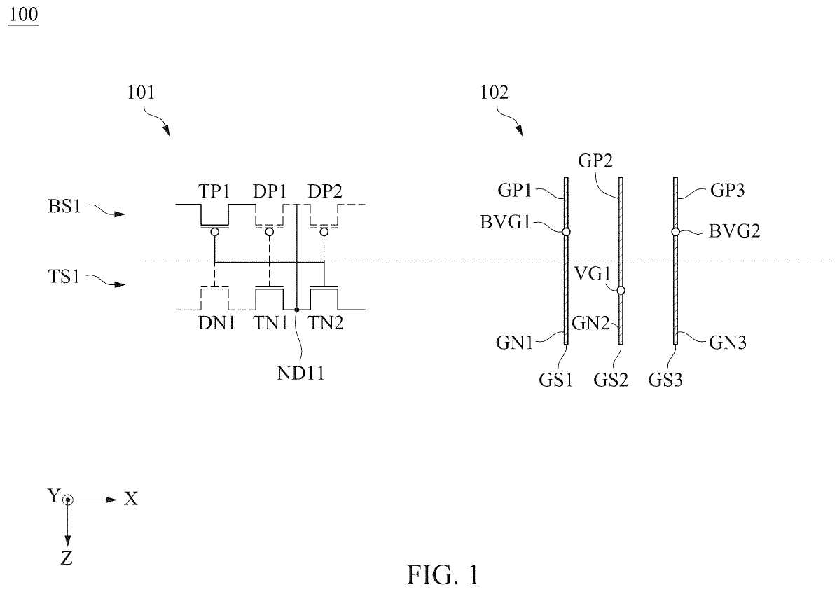

FIG. 1 is a schematic diagram of a semiconductor device 100, illustrated in accordance with some embodiments of the present disclosure. FIG. 1 includes a circuit diagram 101 of the semiconductor device 100 and a cross-sectional view diagram 102 of the semiconductor device 100.

As illustratively shown in FIG. 1, the semiconductor device 100 includes a top side TS1 and a bottom side BS1. The top side TS1 and the bottom side BS1 are opposite to each other along a Z direction. In some embodiments, the semiconductor device 100 is implemented by a complementary field-effect transistor (CFET) structure. The bottom side BS1 corresponds to p-type field-effect transistors (pFET), and the top side TS1 corresponds to n-type field-effect transistors (nFET). However, the embodiments of present disclosure are not limited to this. In some alternative embodiments, the bottom side BS1 corresponds to nFET and the top side TS1 corresponds to pFET.

Referring to the circuit diagram 101, the semiconductor device 100 includes switches TP1, TN1, TN2 and dummy structures DN1, DP1, DP2. A control terminal of the switch TP1 is coupled to a control terminal of the switch TN2. The switches TN1, TN2 and the dummy structures DP1, DP2 are coupled to each other at a node ND11. The switch TP1 and the dummy structures DP1, DP2 are disposed at the bottom side BS1, and are arranged in order along an X direction. The dummy structure DN1 and the switches TN1, TN2 are disposed at the top side TS1, and are arranged in order along the X direction. Two terminals of the dummy structure DP1 are coupled to the switch TP1 and the dummy structure DP2, respectively. Two terminals of the switch TN1 are coupled between the switch TN2 and the dummy structure DN1, respectively.

It is noted that a Y direction points out from the paper in FIG. 1. In some embodiments, the X direction, the Y direction and the Z direction are perpendicular with each other. In some embodiments, the switch TP1 is implemented by pFET, and each of the switches TN1 and TN2 is implemented nFET.

Referring to the cross-sectional view diagram 102, the semiconductor device 100 includes gate structures GS1-GS3 and via structures BVG1, BVG2, VG1. The gate structures GS1-GS3 are separated from each other and are arranged in order along the X direction. Each of the gate structures GS1-GS3 is elongated along the Z direction to be disposed at the top side TS1 and the bottom side BS1.

As illustratively shown in FIG. 1, the gate structure GS1 includes gate portions GP1 and GN1. The gate structure GS2 includes gate portions GP2 and GN2. The gate structure GS3 includes gate portions GP3 and GN3. Each of the gate portions GP1-GP3 is disposed at the bottom side BS1. Each of the gate portions GN1-GN3 is disposed at the top side TS1. The via structure BVG1 is coupled to the gate portion GP1. The via structure BVG2 is coupled to the gate portion GP3. The via structure VG1 is coupled to the gate portion GN2.

Referring to the circuit diagram 101 and the cross-sectional view diagram 102, the control terminal of the switch TP1 is implemented by the gate portion GP1. The control terminal of the switch TN1 is implemented by the gate portion GN2. The control terminal of the switch TN2 is implemented by the gate portion GN3. The gate portions GN1, GP2 and GP3 correspond to the dummy structures DN1, DP1 and DP2, respectively. Alternatively stated, the switch TP1 and the dummy structure DN1 share the gate structure GS1, the switch TN1 and the dummy structure DP1 share the gate structure GS2, and the switch TN2 and the dummy structure DN2 share the gate structure GS3,

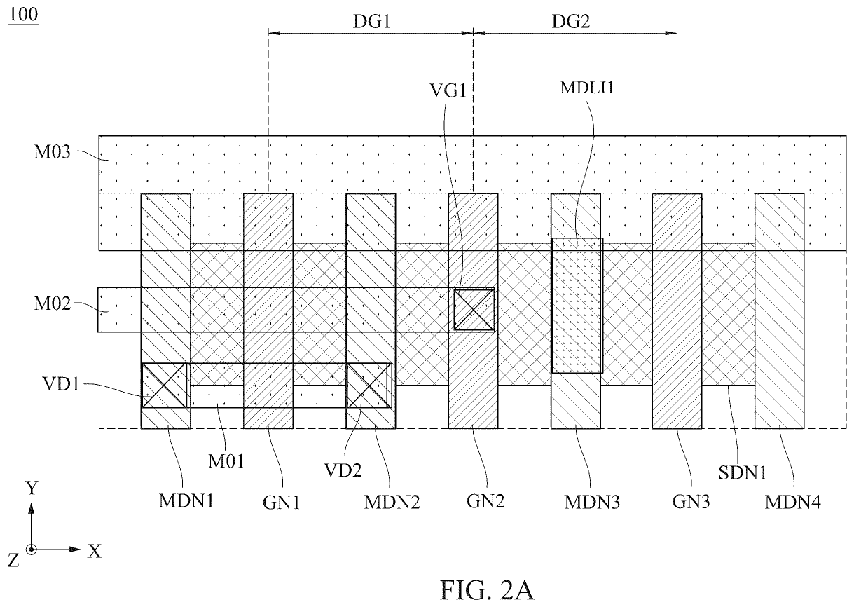

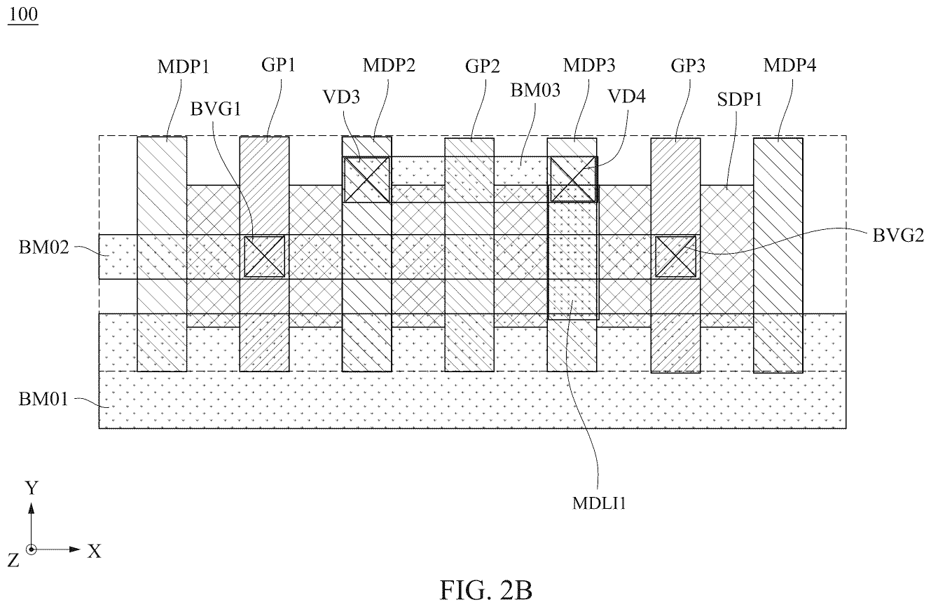

FIG. 2A is a layout diagram a part of a semiconductor device 100 shown in FIG. 1, illustrated in accordance with some embodiments of the present disclosure. In FIG. 2A, the Z direction points out from the paper. Referring to FIG. 1 and FIG. 2A, the semiconductor device 100 further includes a source/drain structure SDN1, conductive segments MDN1-MDN4, M01-M03, MDLI1 and via structures VD1, VD2.

As illustratively shown in FIG. 2A, along the X direction, the conductive segment MDN1, the gate portion GN1, the conductive segment MDN2, the gate portion GN2, the conductive segment MDN3, the gate portion GN3 and the conductive segment MDN4 are arranged in order and are separated from each other. Each of the gate portions GN1-GN3 and the conductive segments MDN1-MDN4 is elongated along the Y direction. Each of the gate portions GN1-GN3 and the conductive segments MDN1-MDN4 is overlapped with and coupled to the source/drain structure SDN1 along the Z direction.

In some embodiments, along the X direction, a distance DG1 between the gate structures GS1 and GS2 is approximately equal to a gate pitch, and a distance DG2 between the gate structures GS3 and GS2 is also approximately equal to the gate pitch. Alternatively stated, the distances DG1 and DG2 are approximately equal to each other.

Along the Y direction, the conductive segments M01-M03 are arranged in order and are separated from each other. The conductive segment M01 is overlapped with each of the gate portion GN1 and the conductive segments MDN1-MDN2 along the Z direction. The conductive segment M02 is overlapped with each of the gate portions GN1-GN2 and the conductive segments MDN1-MDN2 along the Z direction. The conductive segment M03 is overlapped with each of the gate portions GN1-GN3 and the conductive segments MDN1-MDN4 along the Z direction.

In some embodiments, the via structure VD1 is configured to couple the conductive segments M01 and MDN1 to each other. The via structure VD2 is configured to couple the conductive segments M01 and MDN2 to each other. The via structure VG1 is configured to couple the conductive segment M02 and the gate portion GN2 to each other. The conductive segment MDLI1 is overlapped with and coupled to the conductive segment MDN3 along the Z direction.

FIG. 2B is a layout diagram of another part of the semiconductor device 100 shown in FIG. 1, illustrated in accordance with some embodiments of the present disclosure. In FIG. 2B, the Z direction points out from the paper. As illustratively shown in FIG. 2B, the semiconductor device 100 further includes a source/drain structure SDP1, conductive segments MDP1-MDP4, BM01-BM03 and via structures VD3, VD4.

Along the X direction, the conductive segment MDP1, the gate portion GP1, the conductive segment MDP2, the gate portion GP2, the conductive segment MDP3, the gate portion GP3 and the conductive segment MDP4 are arranged in order and are separated from each other. Each of the conductive segments MDP1-MDP4 is elongated along the Y direction. Each of the gate portions GP1-GP3 and the conductive segments MDP1-MDP4 is overlapped with and coupled to the source/drain structure SDP1 along the Z direction.

Along the Y direction, the conductive segments BM01-BM03 are arranged in order and are separated from each other. The conductive segment BM03 is overlapped with each of the gate portion GP2 and the conductive segments MDP2-MDP3 along the Z direction. The conductive segment BM02 is overlapped with each of the gate portions GP1-GP3 and the conductive segments MDP1-MDP3 along the Z direction. The conductive segment BM01 is overlapped with each of the gate portions GP1-GP3 and the conductive segments MDP1-MDP4 along the Z direction.

In some embodiments, the via structure VD3 is configured to couple the conductive segments BM03 and MDP2 to each other. The via structure VD4 is configured to couple the conductive segments BM02 and MDP2 to each other. The via structure BVG1 is configured to couple the conductive segment BM02 and the gate portion GP1 to each other. The via structure BVG2 is configured to couple the conductive segment BM02 and the gate portion GP3 to each other. The conductive segment MDLI1 is overlapped with and coupled to the conductive segment MDP3 along the Z direction. It is noted that the conductive segment MDP2 is coupled to the conductive segment MDN3 through the conductive segments BM03, MDP3 and MDLI1.

Referring to FIG. 2A and FIG. 2B, each of the gate structures GS1-GS3 elongated along the Z direction to be coupled to each of the source/drain structures SDN1 and SDP1. The conductive segment MDLI1 is disposed between the conductive segments MDN3 and MDP3 along the Z direction and configured to couple the conductive segments MDN3 and MDP3 to each other. The conductive segments M01-M03 are disposed above the gate structures GS1-GS3 and the conductive segments MDN1-MDN4 along the Z direction. The conductive segments MDN1-MDN4 are disposed above the conductive segments MDP1-MDP4 along the Z direction. The source/drain structure SDN1 is disposed above the source/drain structure SDP1 along the Z direction. The gate structures GS1-GS3 and the conductive segments MDP1-MDP4 are disposed above the conductive segments BM01-BM03 along the Z direction.

In some embodiments, the source/drain structures SDN1 and SDP1 are implemented by N-type doped material and P-type doped material, respectively. However, the embodiments of present disclosure are not limited to this. In some alternative embodiments, the source/drain structures SDN1 and SDP1 are implemented by P-type doped material and N-type doped material, respectively.

Referring to FIG. 1, FIG. 2A and FIG. 2B, the semiconductor device 100 is implemented by the semiconductor device 200 in some embodiments. The switch TP1 correspond to the gate portion GP1 and the conductive segments MDP1, MDP2. The switch TN1 correspond to the gate portion GN2 and the conductive segments MDN2, MDN3. The switch TN2 correspond to the gate portion GN3 and the conductive segments MDN3, MDN4. Specifically, the control terminals of the switches TP1, TN1 and TN2 are implemented by the gate portions GP1, GN2 and GN3, respectively.

Furthermore, three terminals of the dummy structure DN1 correspond to the gate portion GN1 and the conductive segments MDN1, MDN2, respectively. Three terminals of the dummy structure DP1 correspond to the gate portion GP2 and the conductive segments MDP2, MDP3, respectively. Three terminals of the dummy structure DP2 correspond to the gate portion GP3 and the conductive segments MDP3, MDP4, respectively. The node ND11 corresponds to the conductive segment MDLI1. It is noted that the gate structures GS2 and GS3 are electrically isolated from each other.

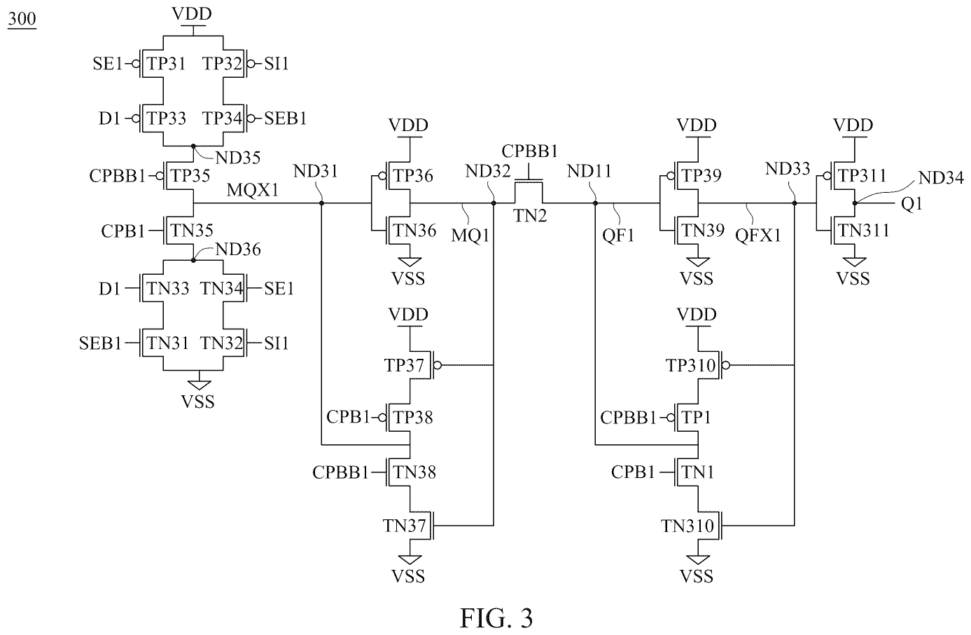

FIG. 3 is a circuit diagram of a semiconductor device 300 corresponding to the semiconductor device 100 shown in FIG. 1, illustrated in accordance with some embodiments of the present disclosure. Referring to FIG. 1 and FIG. 3, the semiconductor device 300 is an embodiment of the semiconductor device 100. The semiconductor device 300 includes the switches TP1, TN1 and TN2 shown in FIG. 1, and further includes switches TP31-TP311 and TN31-TN311.

As illustratively shown in FIG. 3, a terminal of the switch TP31 is configured to receive a reference voltage signal VDD, and another terminal of the switch TP31 is coupled to a terminal of the switch TP33. Another terminal of the switch TP33 is coupled to a node ND35. A terminal of the switch TP32 is configured to receive the reference voltage signal VDD, and another terminal of the switch TP32 is coupled to a terminal of the switch TP34. Another terminal of the switch TP34 is coupled to the node ND35. Two terminals of the switch TP35 are coupled to nodes ND35 and ND31, respectively.

Similarly, a terminal of the switch TN31 is configured to receive a reference voltage signal VSS, and another terminal of the switch TN31 is coupled to a terminal of the switch TN33. Another terminal of the switch TN33 is coupled to a node ND36. A terminal of the switch TN32 is configured to receive the reference voltage signal VSS, and another terminal of the switch TN32 is coupled to a terminal of the switch TN34. Another terminal of the switch TN34 is coupled to the node ND36. Two terminals of the switch TN35 are coupled to the nodes ND36 and ND31, respectively.

In some embodiments, each of control terminals of the switches TP31 and TN34 is configured to receive an enable signal SE1. Each of control terminals of the switches TP34 and TN31 is configured to receive an enable signal SEB1. The enable signals SE1 and SEB1 are complementary with each other. Each of control terminals of the switches TP32 and TN32 is configured to receive a voltage signal SI1. Each of control terminals of the switches TP33 and TN33 is configured to receive a voltage signal D1. Control terminals of the switches TP35 and TN35 is configured to receive clock signals CPBB1 and CPB1, respectively. The clock signals CPBB1 and CPB1 are complementary with each other. Alternatively stated, when one of the clock signals CPBB1 and CPB1 has a logic value of 1, the other one of clock signals CPBB1 and CPB1 has a logic value of 0.

As illustratively shown in FIG. 3, a terminal of the switch TP36 is configured to receive the reference voltage signal VDD, and another terminal of the switch TP36 is coupled to a node ND32. A terminal of the switch TN36 is configured to receive the reference voltage signal VSS, and another terminal of the switch TN36 is coupled to the node ND32. A terminal of the switch TP37 is configured to receive the reference voltage signal VDD, and another terminal of the switch TP37 is coupled to a terminal of the switch TP38. Another terminal of the switch TP38 is coupled to the node ND31. A terminal of the switch TN38 is coupled to the node ND31, and another terminal of the switch TN38 is coupled to a terminal of the switch TN37. Another terminal of the switch TN37 is configured to receive the reference voltage signal VSS.

Each of the control terminals of the switches TP36 and TN36 is coupled to the node ND31. Each of the control terminals of the switches TP37 and TN37 is coupled to the node ND32. Two terminals of the switch TN2 are coupled to the nodes ND32 and ND11, respectively. A control terminal of the switch TP38 is configured to receive the clock signal CPB1. Each of the control terminals of the switches TN38 and TN2 is configured to receive the clock signal CPBB1.

As illustratively shown in FIG. 3, a terminal of the switch TP39 is configured to receive the reference voltage signal VDD, and another terminal of the switch TP39 is coupled to a node ND33. A terminal of the switch TN39 is configured to receive the reference voltage signal VSS, and another terminal of the switch TN39 is coupled to the node ND33. A terminal of the switch TP310 is configured to receive the reference voltage signal VDD, and another terminal of the switch TP310 is coupled to a terminal of the switch TP1. Another terminal of the switch TP1 is coupled to the node ND11. A terminal of the switch TN1 is coupled to the node ND11, and another terminal of the switch TN1 is coupled to a terminal of the switch TN310. Another terminal of the switch TN310 is configured to receive the reference voltage signal VSS.

Each of the control terminals of the switches TP39 and TN39 is coupled to the node ND11. Each of the control terminals of the switches TP310 and TN310 is coupled to the node ND33. The control terminals of the switches TP1 and TN1 are configured to receive the clock signals CPBB1 and CPB1, respectively. A terminal of the switch TP311 is configured to receive the reference voltage signal VDD, and another terminal of the switch TP311 is coupled to a node ND34. A terminal of the switch TN311 is configured to receive the reference voltage signal VSS, and another terminal of the switch TN311 is coupled to the node ND34.

In some embodiments, the switches TN1, TN2 and TN31-TN311 are implemented by nFET, and the switches TP1 and TP31-TP311 are implemented by pFET. Accordingly, in response to the clock signal CPBB1 having the logic value of 0, each of the switches TP35, TN35, TP1 and TN1 is turned on, and each of the switches TP38, TN38 and TN2 is turned off. In response to the clock signal CPBB1 having the logic value of 1, each of the switches TP35, TN35, TP1 and TN1 is turned off, and each of the switches TP38, TN38 and TN2 is turned on.

In some embodiments, the semiconductor device 300 is configured to operate as a flip-flop logic cell. During operation, the semiconductor device 300 is configured to generate data signals MQX1, MQ1, QF1, QFX1 and Q1 at the nodes ND31, ND32, ND11, ND33 and ND34, respectively.

In some approaches, a bipolar transmission gate is utilized in a CFET logic cell. For forming the bipolar transmission gate, processes of gate isolation (GI) and vertical local interconnection (VLI) are used. However, the processes of GI and VLI are challenging in CFET technologies. On the other hand, in order to skip GI and VLI, a larger device area is required.

Compared to above approaches, in some embodiments of the present disclosure, the switch TN2 operates as a unipolar transmission gate in the logic cell, to reduce device area and skip challenging processes. As a result, a smaller device size for higher cell density and process easiness are achieved.

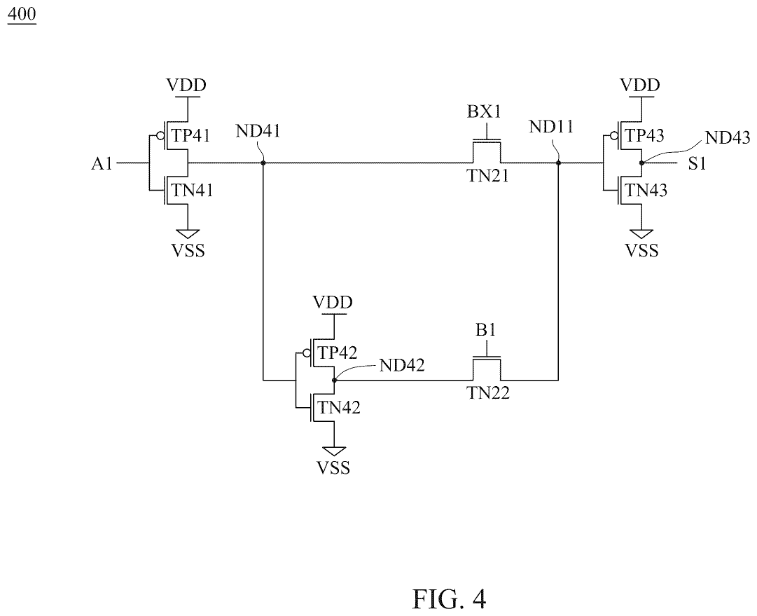

FIG. 4 is a circuit diagram of a semiconductor device 400 corresponding to the semiconductor device 100 shown in FIG. 1, illustrated in accordance with some embodiments of the present disclosure. Referring to FIG. 1 and FIG. 4, the semiconductor device 400 is an embodiment of the semiconductor device 100. The semiconductor device 400 includes switches TN21, TN22, TP41-TP43 and TN41-TN43. In which each one of the switches TN21 and TN22 can be implemented by the switch TN2 shown in FIG. 1.

As illustratively shown in FIG. 4, a terminal of the switch TP41 is configured to receive the reference voltage signal VDD, and another terminal of the switch TP41 is coupled to a terminal of the switch TN41 at a node ND41. Another terminal of the switch TN41 is configured to receive the reference voltage signal VSS. Each of control terminals of the switches TP41 and TN41 is configured to receive a data signal A1. Two terminals of the switch TN21 is coupled to the nodes ND41 and ND11, respectively. A control terminal of the switch TN21 is configured to receive a data signal BX1.

A terminal of the switch TP42 is configured to receive the reference voltage signal VDD, and another terminal of the switch TP42 is coupled to a terminal of the switch TN42 at a node ND42. Another terminal of the switch TN42 is configured to receive the reference voltage signal VSS. Each of control terminals of the switches TP42 and TN42 is coupled to the node ND42. Two terminals of the switch TN22 is coupled to the nodes ND42 and ND11, respectively. A control terminal of the switch TN21 is configured to receive a data signal B1. The data signal B1 and BX1 are complementary with each other. A terminal of the switch TP43 is configured to receive the reference voltage signal VDD, and another terminal of the switch TP43 is coupled to a terminal of the switch TN43 at a node ND43. Another terminal of the switch TN43 is configured to receive the reference voltage signal VSS. Each of control terminals of the switches TP43 and TN43 is coupled to the node ND11.

In some embodiments, the switches TP41-TP43 are implemented by pFET, and the switches TN41-TN43, TN21 and TN22 are implemented by nFET. The data signals B1 and BX1 are complementary with each other. Alternatively stated, when one of the switches TN21 and TN22 is turned on, the other one of the switches TN21 and TN22 is turned off.

In some embodiments, the semiconductor device 400 is configured to operate as a half adder logic cell. During operation, the semiconductor device 400 is configured to generate a data signal S1 by adding the data signals A1 and B1.

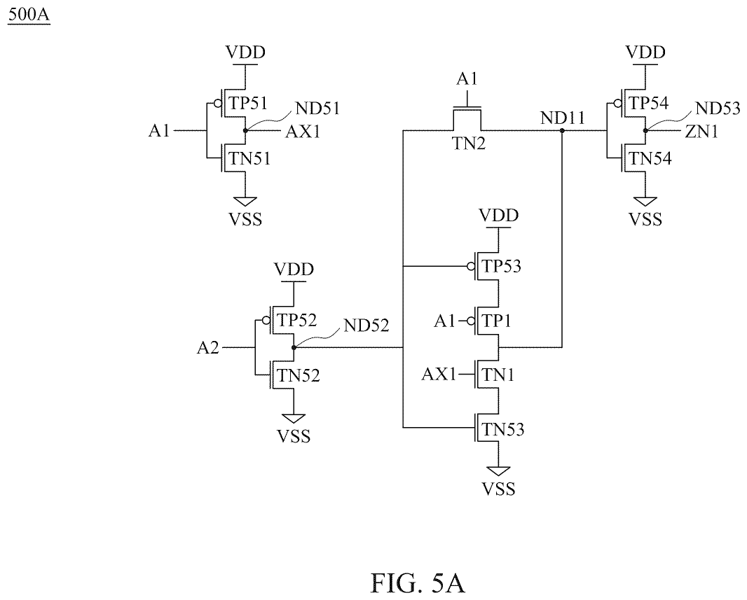

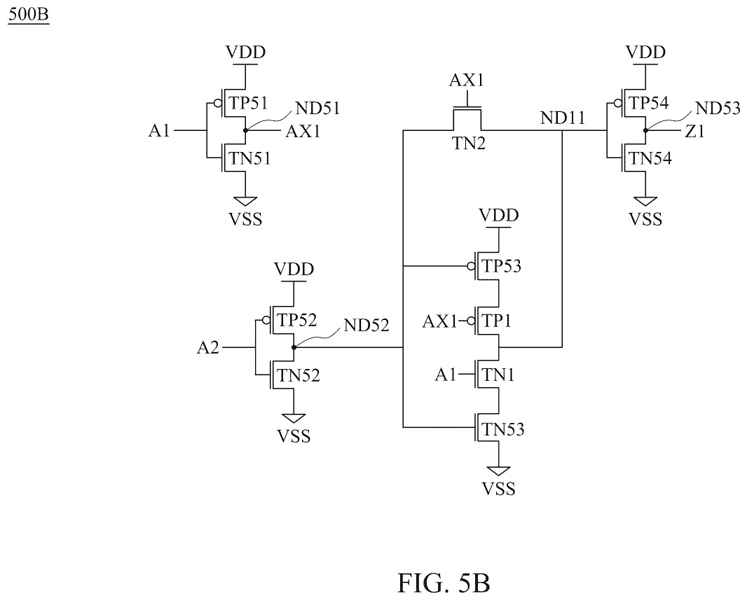

FIG. 5A is a circuit diagram of a semiconductor device 500A corresponding to the semiconductor device 100 shown in FIG. 1, illustrated in accordance with some embodiments of the present disclosure. Referring to FIG. 1 and FIG. 5A, the semiconductor device 500A is an embodiment of the semiconductor device 100. The semiconductor device 500A includes the switches TN1, TN2 and TP1, and further includes switches TP51-TP54 and TN51-TN54.

As illustratively shown in FIG. 5A, a terminal of the switch TP51 is configured to receive the reference voltage signal VDD, and another terminal of the switch TP51 is coupled to a terminal of the switch TN51 at a node ND51. Another terminal of the switch TN51 is configured to receive the reference voltage signal VSS. Each of control terminals of the switches TP51 and TN51 is configured to receive the data signal A1. The switches TP41 and TN41 are configured to generate a data signal AX1 which is complementary with the data signal A1. In some embodiments, the switches TP41 and TN41 are configured to operate as an inverter.

A terminal of the switch TP52 is configured to receive the reference voltage signal VDD, and another terminal of the switch TP52 is coupled to a terminal of the switch TN52 at a node ND52. Another terminal of the switch TN52 is configured to receive the reference voltage signal VSS. Each of control terminals of the switches TP52 and TN52 is configured to receive a data signal A2. Two terminals of the switch TN2 are coupled to the nodes ND52 and ND11, respectively. A control terminal of the switch TN2 is configured to receive the data signal A1.

A terminal of the switch TP53 is configured to receive the reference voltage signal VDD, and another terminal of the switch TP53 is coupled to a terminal of the switch TP1. Another terminal of the switch TP1 is coupled to a terminal of the switch TN1 at the node ND11. Another terminal of the switch TP1 coupled to a terminal of the switch TN53. Another terminal of the switch TN53 is configured to receive the reference voltage signal VSS. Each of control terminals of the switches TP53 and TN53 is coupled to the node ND52. Control terminals of the switches TP1 and TN1 are configured to receive the data signals A1 and AX1, respectively.

A terminal of the switch TP54 is configured to receive the reference voltage signal VDD, and another terminal of the switch TP54 is coupled to a terminal of the switch TN54 at a node ND54. Another terminal of the switch TN54 is configured to receive the reference voltage signal VSS. Each of control terminals of the switches TP54 and TN54 is coupled to the node ND11.

In some embodiments, the switches TP1 and TP51-TP54 are implemented by pFET, and the switches TN1, TN2 and TN51-TN54 are implemented by nFET. In some embodiments, the semiconductor device 500A is configured to operate as an XNOR logic cell. During operation, the semiconductor device 500A is configured to generate a data signal ZN1 at the node ND53, by performing an XNOR logic operation to the data signals A1 and A2.

FIG. 5B is a circuit diagram of a semiconductor device 500B corresponding to the semiconductor device 500A shown in FIG. 5A, illustrated in accordance with some embodiments of the present disclosure. Referring to FIG. 5A and FIG. 5B, the semiconductor device 500B is an alternative embodiment of the semiconductor device 500A. FIG. 5B follows a similar labeling convention to that of FIG. 5A. For brevity, the discussion will focus more on differences between the semiconductor device 500B and the semiconductor device 500A than on similarities.

Compared to the semiconductor device 500A, in the semiconductor device 500B, the control terminal of the switch TN2 is configured to receive the data signal AX1. The control terminal of the switch TN1 is configured to receive the data signal A1. The control terminal of the switch TP1 is configured to receive the data signal AX1.

In some embodiments, the semiconductor device 500B is configured to operate as an XOR logic cell. During operation, the semiconductor device 500B is configured to generate a data signal Z1 at the node ND53, by performing an XOR logic operation to the data signals A1 and A2.

Referring to FIG. 1 to FIG. 5B, the conductive segment MDN4 corresponds to the nodes ND32, ND41 and ND52. Accordingly, when the switch TN2 is turned off, the conductive segment MDN4 is electrically isolated from the node ND11 which corresponds to the conductive segment MDLI1. In some embodiments, along the X direction, a distance between the gate portion GN3 and the conductive segment MDLI1 is approximately equal to a distance between the gate portion GN3 and the conductive segment MDN4.

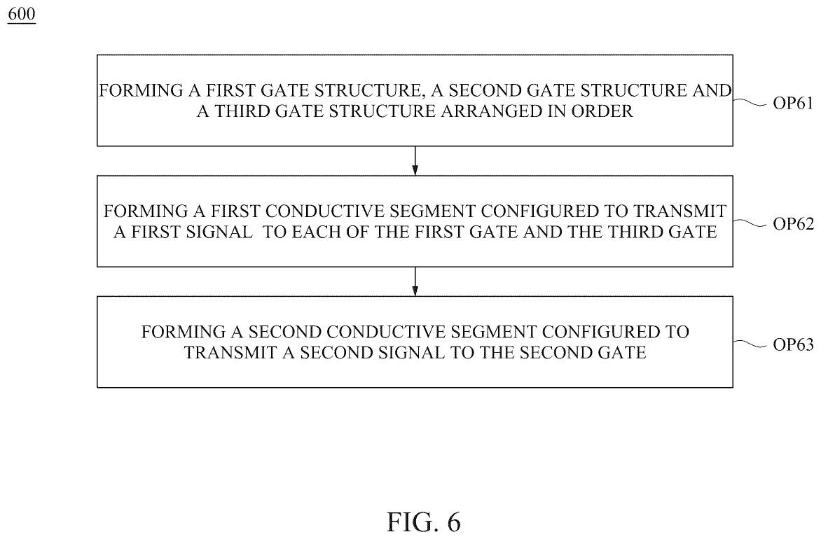

FIG. 6 is a flowchart diagram of a method 600 for fabricating the semiconductor devices described above, illustrated in accordance with some embodiments of the present disclosure. The method 600 includes operations OP61-OP63.

During the operation OP61, a first gate structure, a second gate structure and a third gate structure arranged in order are formed. For example, the gate structures GS1-GS3 arranged in order are formed.

During the operation OP62, a first conductive segment configured to transmit a first signal to each of the first gate structure and the third gate structure is formed. For example, the conductive segment BM02 configured to transmit the clock signal CPBB1 to each of the gate structures GS1 and GS3 is formed.

During the operation OP63, a second conductive segment configured to transmit a second signal to the second gate structure is formed. For example, the conductive segment M02 configured to transmit the clock signal CPB1 to the gate structure GS2 is formed.

In some embodiments, the second signal is complementary with the first signal, and a distance between the first gate structure and the second gate structure is approximately equal to a distance between the third gate structure and the second gate structure.

For example, the clock signal CPB1 is complementary with the clock signal CPBB1, and the distance DG1 between the gate structures GS1 and GS2 is approximately equal to the distance DG2 between the gate structures GS3 and GS2.

In some embodiments, the first conductive segment is overlapped with each of the first gate structure and the third gate structure, and the second conductive segment is overlapped with each of the first gate structure and the second gate structure.

For example, the conductive segment BM02 is overlapped with each of the gate structures GS1 and GS3, and the conductive segment M02 is overlapped with each of the gate structures GS1 and GS2.

In some embodiments, the second gate structure and the third gate structure are electrically isolated from each other. For example, the gate structures GS2 and GS3 are electrically isolated from each other.

In some embodiments, the first gate structure corresponds to each of a first switch and a first dummy structure, the second gate structure corresponds to each of a second switch and a second dummy structure, the third gate structure corresponds to each of a third switch and a third dummy structure, and the third dummy structure, the second dummy structure, the second switch and the third switch are coupled to each other at a first node.

For example, the gate structure GS1 corresponds to each of the switch TP1 and the dummy structure DN1, the gate structure GS2 corresponds to each of the switch TN1 and the dummy structure DP1, the gate structure GS3 corresponds to each of the switch TN2 and the dummy structure DP2, and the dummy structure DP2, DP1 and the switches TN1, TN2 are coupled to each other at the node ND11.

In some embodiments, the method 600 further includes: forming a third conductive segment corresponding to the first node, and forming a fourth conductive segment corresponding to a terminal of the third switch. When the third switch is turned off, the third conductive segment and the fourth conductive segment are electrically isolated from each other.

For example, the conductive segment MDLI1 corresponding to the node ND11 is formed. The conductive segment MDN4 corresponding to a terminal of the switch TN2 is formed. When the switch TN2 is turned off the conductive segments MDLI1 and MDN4 are electrically isolated from each other.

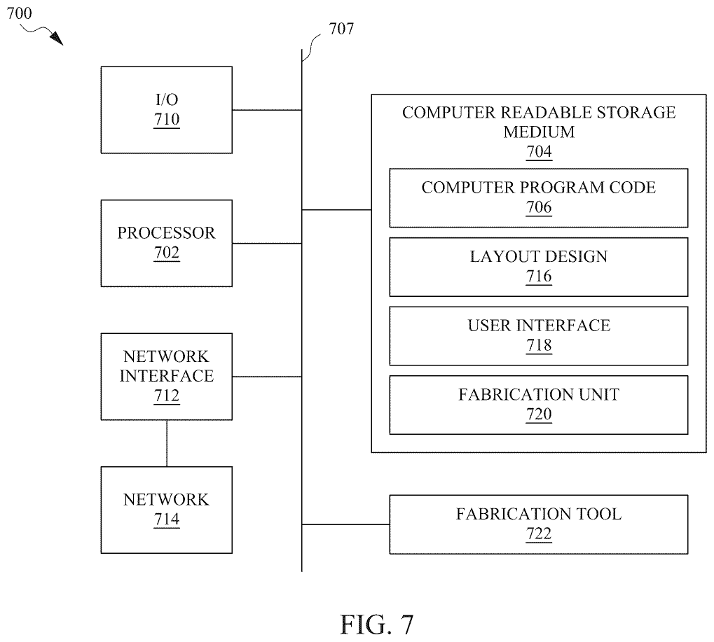

FIG. 7 is a schematic view of a system 700 for designing and manufacturing at least one of the semiconductor devices described above, in accordance with some embodiments of the present disclosure. The system 700 generates or places one or more IC layout designs corresponding to at least one of the semiconductor devices as described herein. In some embodiments, the system 700 manufactures one or more semiconductor devices based on the one or more IC layout designs, as described herein. The system 700 includes a hardware processor 702 and a non-transitory, computer readable storage medium 704 encoded with, e.g., storing, the computer program code 706, e.g., a set of executable instructions. The computer readable storage medium 704 is configured for interfacing with manufacturing machines for producing the semiconductor device. The processor 702 is electrically coupled to the computer readable storage medium 704 by a bus 707. The processor 702 is also electrically coupled to an I/O interface 710 by the bus 707. A network interface 712 is also electrically connected to the processor 702 by the bus 707. Network interface 712 is connected to a network 714, so that the processor 702 and the computer readable storage medium 704 are capable of connecting to external elements via network 714. The processor 702 is configured to execute the computer program code 706 encoded in the computer readable storage medium 704 in order to cause the system 700 designing and manufacturing at least one of the semiconductor devices described above.

In some embodiments, the processor 702 is a central processing unit (CPU), a multi-processor, a distributed processing system, an application specific integrated circuit (ASIC), and/or a suitable processing unit.

In some embodiments, the computer readable storage medium 704 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 704 includes a compact disk-read only memory (CD-ROM), a compact disk-read/write (CD-R/W), and/or a digital video disc (DVD).

In some embodiments, the storage medium 704 also stores information needed for designing and manufacturing at least one of the semiconductor devices 100, 200, 300, 400 and 500, such as layout design 716, user interface 718, fabrication unit 720, and/or a set of executable instructions to designing and manufacturing at least one of the semiconductor devices described above.

In some embodiments, the storage medium 704 stores instructions (e.g., the computer program code 706) for interfacing with manufacturing machines. The instructions (e.g., the computer program code 706) enable the processor 702 to generate manufacturing instructions readable by the manufacturing machines to effectively implement the semiconductor devices described above.

The system 700 includes the I/O interface 710. The I/O interface 710 is coupled to external circuitry. In some embodiments, the I/O interface 710 includes a keyboard, keypad, mouse, trackball, trackpad, and/or cursor direction keys for communicating information and commands to the processor 702.

The system 700 also includes the network interface 712 coupled to the processor 702. The network interface 712 allows the system 700 to communicate with the network 714, to which one or more other computer systems are connected. The network interface 712 includes wireless network interfaces such as BLUETOOTH, WIFI, WIMAX, GPRS, or WCDMA; or wired network interface such as ETHERNET, USB, or IEEE-13154. In some embodiments, the designing and manufacturing of at least one of the semiconductor devices described above is implemented in two or more systems 700, and information such as layout design, user interface and fabrication unit are exchanged between different systems 700 by the network 714.

The system 700 is configured to receive information related to a layout design through the I/O interface 710 or network interface 712. The information is transferred to the processor 702 by the bus 707 to determine a layout design for producing an IC. The layout design is then stored in the computer readable medium 704 as the layout design 716. The system 700 is configured to receive information related to a user interface through the I/O interface 710 or network interface 712. The information is stored in the computer readable medium 704 as the user interface 718. The system 700 is configured to receive information related to a fabrication unit through the I/O interface 710 or network interface 712. The information is stored in the computer readable medium 704 as the fabrication unit 720. In some embodiments, the fabrication unit 720 includes fabrication information utilized by the system 700.

In some embodiments, the designing and manufacturing of at least one of the semiconductor devices described above is implemented as a standalone software application for execution by a processor. In some embodiments, the designing and manufacturing of at least one of the semiconductor devices described above is implemented as a software application that is a part of an additional software application. In some embodiments, the designing and manufacturing of at least one of the semiconductor devices described above is implemented as a plug-in to a software application. In some embodiments, the designing and manufacturing of at least one of the semiconductor devices described above is implemented as a software application that is a portion of an EDA tool. In some embodiments, the designing and manufacturing of at least one of the semiconductor devices described above is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the semiconductor devices described above is implemented by a manufacturing device to manufacture an integrated circuit using a set of masks manufactured based on one or more layout designs generated by the system 700. In some embodiments, the system 700 includes a manufacturing device (e.g., fabrication tool 722) to manufacture an integrated circuit using a set of masks manufactured based on one or more layout designs of the present disclosure.

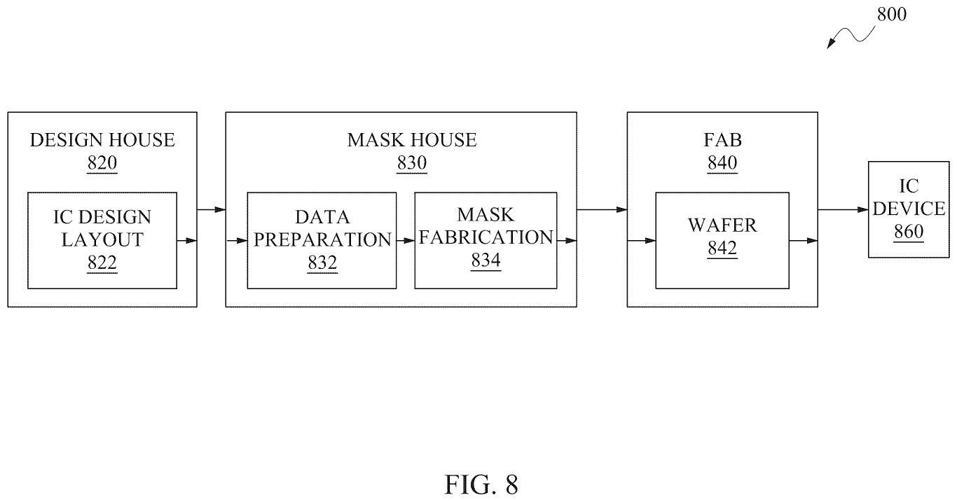

FIG. 8 is a block diagram of an integrated circuit (IC)/semiconductor device manufacturing system 800, and an IC manufacturing flow associated therewith, in accordance with some embodiments of the present disclosure. In some embodiments, the method 600 shown in FIG. 6 is performed by the IC manufacturing system 800.

In FIG. 8, the IC manufacturing system 800 includes entities, such as a design house 820, a mask house 830, and an IC manufacturer/fabricator (“fab”) 840, that interact with one another in the design, development, and manufacturing cycles and/or services related to manufacturing an IC device (semiconductor device) 860 including at least one of the semiconductor devices described above. The entities in system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 840 is owned by a single company. In some embodiments, two or more of design house 820, mask house 830, and IC fab 840 coexist in a common facility and use common resources.

The design house (or design team) 820 generates an IC design layout 822. The IC design layout 822 includes various geometrical patterns designed for the IC device 860. The geometrical patterns correspond to patterns of metal, oxide, or semiconductor layers that make up the various components of the IC device 860 to be fabricated. The various layers combine to form various IC features. For example, a portion of the IC design layout 822 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 820 implements a proper design procedure to form the IC design layout 822. The design procedure includes one or more of logic design, physical design or place and route. The IC design layout 822 is presented in one or more data files having information of the geometrical patterns. For example, the IC design layout 822 can be expressed in a GDSII file format or DFII file format.

The mask house 830 includes mask data preparation 832 and mask fabrication 834. The mask house 830 uses the IC design layout 822 to manufacture one or more masks to be used for fabricating the various layers of the IC device 860 according to the IC design layout 822. The mask house 830 performs the mask data preparation 832, where the IC design layout 822 is translated into a representative data file (“RDF”). The mask data preparation 832 provides the RDF to the mask fabrication 834. The mask fabrication 834 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 832 to comply with particular characteristics of the mask writer and/or requirements of the IC fab 840. In FIG. 8, the mask data preparation 832 and mask fabrication 834 are illustrated as separate elements. In some embodiments, the mask data preparation 832 and mask fabrication 834 can be collectively referred to as mask data preparation.

In some embodiments, the mask data preparation 832 includes optical proximity correction (OPC) which uses lithography enhancement techniques to compensate for image errors, such as those that can arise from diffraction, interference, other process effects and the like. OPC adjusts the IC design layout 822. In some embodiments, the mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 832 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 834, which may undo part of the modifications performed by OPC in order to meet mask creation rules.

In some embodiments, the mask data preparation 832 includes lithography process checking (LPC) that simulates processing that will be implemented by the IC fab 840 to fabricate the IC device 860. LPC simulates this processing based on the IC design layout 822 to create a simulated manufactured device, such as the IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 822.

It should be understood that the above description of the mask data preparation 832 has been simplified for the purposes of clarity. In some embodiments, the mask data preparation 832 includes additional features such as a logic operation (LOP) to modify the IC design layout according to manufacturing rules. Additionally, the processes applied to the IC design layout 822 during the mask data preparation 832 may be executed in a variety of different orders.

After the mask data preparation 832 and during mask fabrication 834, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 834 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 840 is an IC fabrication entity that includes one or more manufacturing facilities for the fabrication of a variety of different IC products. In some embodiments, the IC fab 840 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 840 uses the mask (or masks) fabricated by the mask house 830 to fabricate the IC device 860. Thus, the IC fab 840 at least indirectly uses the IC design layout 822 to fabricate the IC device 860. In some embodiments, a semiconductor wafer is fabricated by the IC fab 840 using the mask (or masks) to form the IC device 860. The semiconductor wafer 842 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a device. The device includes a first gate structure, a second gate structure, a third gate structure and a first conductive segment. The first gate structure corresponds to a control terminal of a first switch. The second gate structure corresponds to a control terminal of a second switch. The third gate structure corresponds to a control terminal of a third switch, and coupled to the first gate structure. The first conductive segment is configured to couple the first switch, the second switch and the third switch to each other, and disposed between the second gate structure and the third gate structure. A distance between the first gate structure and the second gate structure is approximately equal to a distance between the third gate structure and the second gate structure.

Also disclosed is a device. The device includes a first switch, a second switch and a third switch. The first switch shares a first gate structure with a first dummy structure. The second switch shares a second gate structure with a second dummy structure. The third switch shares a third gate structure with a third dummy structure. The second gate structure is disposed between the first gate structure and the third gate structure, a control terminal of the first switch is coupled to a control terminal of the third switch, and the first dummy structure, the second dummy structure, the second switch and the third switch are coupled to each other at a first node.

Also disclosed is a method. The method includes: forming a first gate structure, a second gate structure and a third gate structure arranged in order; forming a first conductive segment configured to transmit a first signal to each of the first gate structure and the third gate structure; and forming a second conductive segment configured to transmit a second signal to the second gate structure. The second signal is complementary with the first signal, and a distance between the first gate structure and the second gate structure is approximately equal to a distance between the third gate structure and the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first gate structure corresponding to a control terminal of a first switch;
a second gate structure corresponding to a control terminal of a second switch;
a third gate structure corresponding to a control terminal of a third switch, and coupled to the first gate structure; and
a first conductive segment configured to couple the first switch, the second switch and the third switch to each other, and disposed between the second gate structure and the third gate structure,
wherein a distance between the first gate structure and the second gate structure is approximately equal to a distance between the third gate structure and the second gate structure.

2. The device of claim 1, wherein the third switch is configured to operate as a unipolar transmission gate.

3. The device of claim 1, further comprising:
a second conductive segment overlapped with each of the first gate structure, the third gate structure and the first conductive segment, and coupled to each of the first gate structure and the third gate structure.

4. The device of claim 3, further comprising:
a third conductive segment overlapped with each of the first gate structure and the second gate structure, and configured to transmit a first clock signal to the second gate structure,
wherein the second conductive segment is configured to transmit a second clock signal complementary with the first clock signal.

5. The device of claim 1, further comprising:
a first dummy structure sharing the second gate structure with the second switch; and
a second dummy structure sharing the third gate structure with the third switch, and coupled to the first dummy structure.

6. The device of claim 1, wherein the second gate structure and the third gate structure are electrically isolated from each other.

7. The device of claim 1, further comprising:
a second conductive segment corresponding to a first terminal of the third switch,
wherein the first conductive segment corresponding to a second terminal of the third switch, and
when the third switch is turned off, the second conductive segment and the first conductive segment are electrically isolated from each other.

8. A device, comprising:
a first switch sharing a first gate structure with a first dummy structure;
a second switch sharing a second gate structure with a second dummy structure; and
a third switch sharing a third gate structure with a third dummy structure,
wherein the second gate structure is disposed between the first gate structure and the third gate structure,
a control terminal of the first switch is coupled to a control terminal of the third switch, and
the first dummy structure, the second dummy structure, the second switch and the third switch are coupled to each other at a first node.

9. The device of claim 8, wherein
two terminals of the second dummy structure are coupled to the first switch and the third dummy structure, respectively, and
two terminals of the second switch are coupled to the first dummy structure and the third switch, respectively.

10. The device of claim 8, wherein a distance between the first gate structure and the second gate structure is approximately equal to a distance between the third gate structure and the second gate structure.

11. The device of claim 8, wherein each of the control terminal of the first switch and the control terminal of the third switch is configured to receive a first signal, and
a control terminal of the second switch is configured to receive a second signal complementary with the first signal.

12. The device of claim 11, further comprising:
a first conductive segment overlapped with each of the first gate structure, the third gate structure, and configured to transmit the first signal.

13. The device of claim 12, further comprising:
a second conductive segment overlapped with each of the first gate structure and the second gate structure, and configured to transmit the second signal to the second gate structure.

14. The device of claim 8, wherein the second gate structure and the third gate structure are electrically isolated from each other.

15. The device of claim 8, further comprising:
a first conductive segment corresponding to the first node; and
a second conductive segment corresponding to a terminal of the third switch,
when the third switch is turned off, the second conductive segment and the first conductive segment are electrically isolated from each other.

16. A method, comprising:
forming a first gate structure, a second gate structure and a third gate structure arranged in order;
forming a first conductive segment configured to transmit a first signal to each of the first gate structure and the third gate structure; and
forming a second conductive segment configured to transmit a second signal to the second gate structure,
wherein the second signal is complementary with the first signal, and
a distance between the first gate structure and the second gate structure is approximately equal to a distance between the third gate structure and the second gate structure.

17. The method of claim 16, wherein
the first conductive segment is overlapped with each of the first gate structure and the third gate structure, and
the second conductive segment is overlapped with each of the first gate structure and the second gate structure.

18. The method of claim 16, wherein the second gate structure and the third gate structure are electrically isolated from each other.

19. The method of claim 16, wherein
the first gate structure corresponds to each of a first switch and a first dummy structure,
the second gate structure corresponds to each of a second switch and a second dummy structure,
the third gate structure corresponds to each of a third switch and a third dummy structure, and
the third dummy structure, the second dummy structure, the second switch and the third switch are coupled to each other at a first node.

20. The method of claim 19, further comprising:
forming a third conductive segment corresponding to the first node; and
forming a fourth conductive segment corresponding to a terminal of the third switch,
wherein when the third switch is turned off, the third conductive segment and the fourth conductive segment are electrically isolated from each other.
